(19) United States
(12) Patent Application Publication
(10) Pub. No.: US 2026/0136894 A1
(43) Pub. Date: May 14, 2026

(54) SEMICONDUCTOR DEVICE AND METHOD OF DETECTING FAILURE THEREIN

(71) Applicant: Samsung Electronics Co., Ltd., Suwon-si, (KR)

(72) Inventors: Myungjin Chung, Suwon-si (KR); Jinkyu Kim, Suwon-si, (KR); Inhyun Song, Suwon-si, (KR); Hyung-Mo Yang, Suwon-si, (KR); Eunguk Chung, Suwon-si, (KR); Wookhyun Jo, Suwon-si, (KR); Keun Hwi Cho, Suwon-si, (KR)

(73) Assignee: Samsung Electronics Co., Ltd., Suwon-si (KR)

(21) Appl. No.: 19/303,951

(22) Filed: Aug. 19, 2025

(30) Foreign Application Priority Data
Nov. 12, 2024 (KR) 10-2024-0160507

(51) Int. Cl. H01L 21/66; G01R 31/28; G01R 31/307; H01L 23/48; H01L 23/528

(52) U.S. Cl. CPC H10P 74/27; G01R 31/2884; G01R 31/307; H10W 20/20; H10W 20/43

(57) ABSTRACT

A semiconductor device may include a substrate including front and rear surfaces, which are opposite to each other, a first transistor disposed on the front surface of the substrate, the first transistor including a first gate electrode and first source/drain patterns adjacent to both sides of the first gate, a first interlayer insulating layer on the first transistor, a first front-side detection structure disposed on the first interlayer insulating layer and connected to the first gate electrode, a first back-side detection structure adjacent the rear surface of the substrate, and a first penetration detection structure connecting the first front-side detection structure to the first back-side detection structure. The first penetration detection structure may include a front-side contact penetrating the first interlayer insulating layer and a first back-side contact penetrating a portion of the substrate.

### CROSS-REFERENCE TO RELATED APPLICATIONS

This U.S. non-provisional patent application claims priority under 35 U.S.C. § 119 to Korean Patent Application No. 10-2024-0160507, filed on Nov. 12, 2024, in the Korean Intellectual Property Office, the entire contents of which are hereby incorporated by reference.

### BACKGROUND

The present disclosure relates to a semiconductor device and a method of detecting a failure therein.

A semiconductor device includes an integrated circuit consisting of metal-oxide-semiconductor field-effect transistors (MOS-FETs). To meet an increasing demand for a semiconductor device with a small pattern size and a reduced design rule, the MOS-FETs are being aggressively scaled down. As MOSFETs are scaled down, defects or failures may occur in the semiconductor device. Failure analysis is widely used in the semiconductor industry to detect defects or failures in semiconductor devices (e.g., integrated circuits). However, as the design of semiconductor devices becomes more complex, it becomes increasingly difficult to detect defects or failures.

### SUMMARY

Some embodiments of the inventive concept provides a semiconductor device that is configured to easily detect a defect or a failure therein.

Some embodiments of the inventive concept provides a method of easily detecting a failure in a semiconductor device.

According to some embodiments of the inventive concept, a semiconductor device may include a substrate including a front surface and a rear surface, which are opposite to each other, a first transistor adjacent the front surface of the substrate, the first transistor including a first gate electrode and first source/drain patterns adjacent to both sides of the first gate electrode, a first interlayer insulating layer disposed on the first transistor, a first front-side detection structure disposed on the first interlayer insulating layer and connected to the first gate electrode, a first back-side detection structure adjacent the rear surface of the substrate, and a first penetration detection structure connecting the first front-side detection structure to the first back-side detection structure. The first penetration detection structure may include a front-side contact penetrating the first interlayer insulating layer and a first back-side contact penetrating a portion of the substrate.

According to some embodiments of the inventive concept, a semiconductor device may include a substrate including a front surface and a rear surface, which are opposite to each other, a first transistor adjacent the front surface of the substrate, the first transistor including a first gate electrode and first source/drain patterns adjacent to both sides of the first gate electrode, a second transistor adjacent the front surface of the substrate, the second transistor including a second gate electrode and second source/drain patterns adjacent to both sides the second gate electrode, a first interlayer insulating layer disposed on the first transistor, a first front-side detection structure disposed on the first interlayer insulating layer and connected to the first gate electrode, a second front-side detection structure disposed on the first interlayer insulating layer and connected to the second gate electrode, a first back-side detection structure adjacent the rear surface of the substrate, a first penetration via penetrating the first interlayer insulating layer and the substrate and connecting the first front-side detection structure to the first back-side detection structure, a second back-side detection structure adjacent the rear surface of the substrate, and a second penetration via penetrating the first interlayer insulating layer and the substrate and connecting the second front-side detection structure to the second back-side detection structure. A first level of a lower end of the first back-side detection structure may be equal to a second level of a lower end of the second back-side detection structure.

According to some embodiments of the inventive concept, a semiconductor device may include a substrate including a front surface and a rear surface, which are opposite to each other, a flip-flop circuit adjacent the front surface of the substrate, a first transistor adjacent the front surface of the substrate, the first transistor including a first gate electrode and first source/drain patterns adjacent to both sides of the first gate electrode and being included in the flip-flop circuit, a first interlayer insulating layer disposed on the first transistor, a first front-side detection structure disposed on the first interlayer insulating layer and connected to the first gate electrode, a first back-side detection structure adjacent the rear surface of the substrate, a first penetration detection structure connecting the first front-side detection structure to the first back-side detection structure, a power line adjacent the rear surface of the substrate, and a back-side interconnection structure connected to the power line. The first penetration detection structure may include a front-side contact penetrating the first interlayer insulating layer, a first back-side contact penetrating a portion of the substrate, and a connection conductive pattern between the front-side contact and the first back-side contact. The connection conductive pattern and the first source/drain patterns may be doped with the same dopants.

According to some embodiments of the inventive concept, a method of detecting a failure in a semiconductor device may include obtaining the semiconductor device, which includes a flip-flop circuit disposed on a substrate, a front-side detection structure connected to the flip-flop circuit, a back-side detection structure adjacent a rear surface of the substrate, and a penetration detection structure penetrating the substrate and connecting the front-side detection structure to the back-side detection structure, and irradiating a lower end of the back-side detection structure with an electron beam to detect a failure in the flip-flop circuit. In some embodiments, the semiconductor device further comprises a power line, which is adjacent the rear surface of the substrate, and a back-side interconnection structure, which is connected to the power line, the lower end of the back-side detection structure is higher than a lower end of the back-side interconnection structure. The method may further comprises partially removing a rear portion of the semiconductor device to expose the lower end of the back-side detection structure, before the irradiating of the electron beam.

### BRIEF DESCRIPTION OF THE DRAWINGS

FIG. 1 is a sectional view illustrating a semiconductor device according to some embodiments of the inventive concept.

FIGS. 2A to 2C are enlarged diagrams illustrating a portion ‘P1’ of FIG. 1.

FIG. 3 is a sectional view illustrating a transistor according to some embodiments of the inventive concept.

FIGS. 4A and 4B are enlarged diagrams illustrating a portion ‘P2’ of FIG. 1.

FIG. 5 is a schematic diagram illustrating a method of detecting a failure in the semiconductor device of FIG. 1.

FIG. 6A is a sectional view illustrating a semiconductor device according to some embodiments of the inventive concept.

FIG. 6B is a schematic diagram illustrating a method of detecting a failure in the semiconductor device of FIG. 6A.

FIG. 7A is a sectional view illustrating a semiconductor device according to some embodiments of the inventive concept.

FIGS. 7B and 7C are plan views illustrating a portion of the semiconductor device of FIG. 7A.

FIG. 8 is a schematic diagram illustrating a method of detecting a failure in the semiconductor device of FIG. 7A.

FIG. 9 is a sectional view illustrating a semiconductor device according to some embodiments of the inventive concept.

FIG. 10 is a sectional view illustrating a semiconductor device according to some embodiments of the inventive concept.

FIG. 11 is a sectional view illustrating a semiconductor device according to some embodiments of the inventive concept.

FIG. 12 is a conceptual diagram illustrating a semiconductor device according to some embodiments of the inventive concept.

### DETAILED DESCRIPTION

Example embodiments of the inventive concepts will now be described more fully with reference to the accompanying drawings, in which example embodiments are shown. In this specification, terms such as first, second, and so on, which indicate an order, are used to distinguish components with the same or similar functions from one another, and the numbering may vary depending on the order in which they are mentioned.

According to some embodiments of the inventive concept, e-beam fault isolation (EFI) may be performed through the rear side of a semiconductor device using a back-side detection structure. The detection structures described herein are less complex because they involve fewer metal layers and are easier to fabricate. For example, back-side failure detection in accordance with some embodiments may omit the use supporting wafers.

It should be noted that the back-side detection structures described herein are not limited to use in connection with beam fault isolation, but may be used with other types of techniques for testing semiconductor devices.

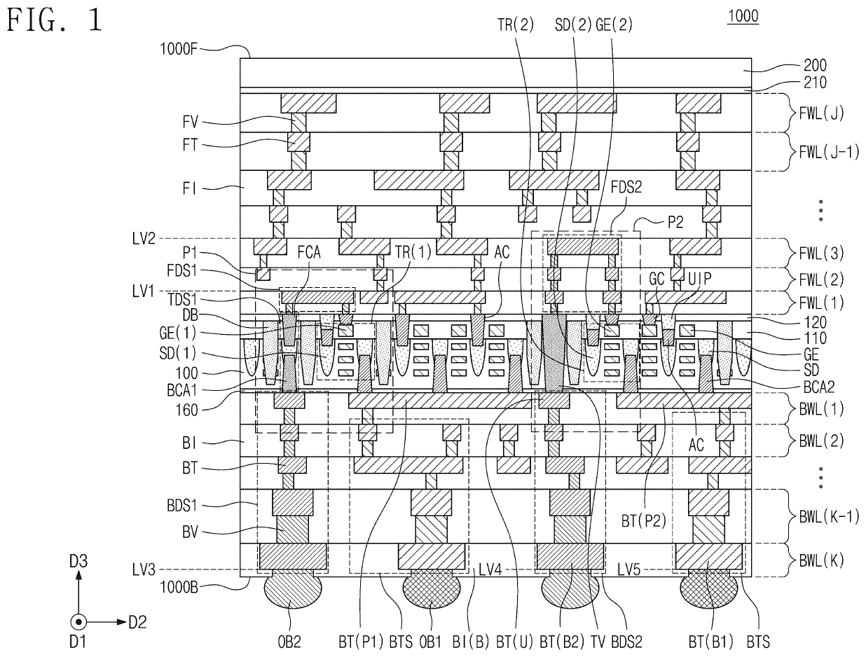

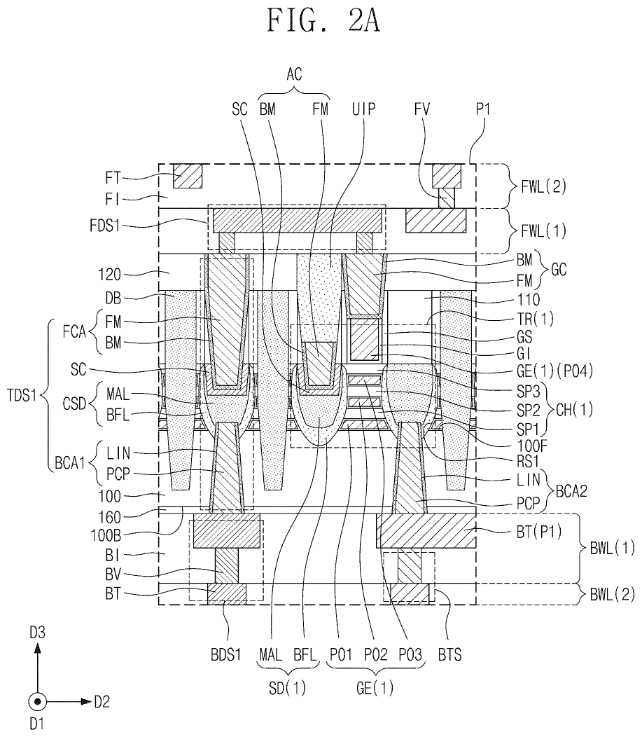

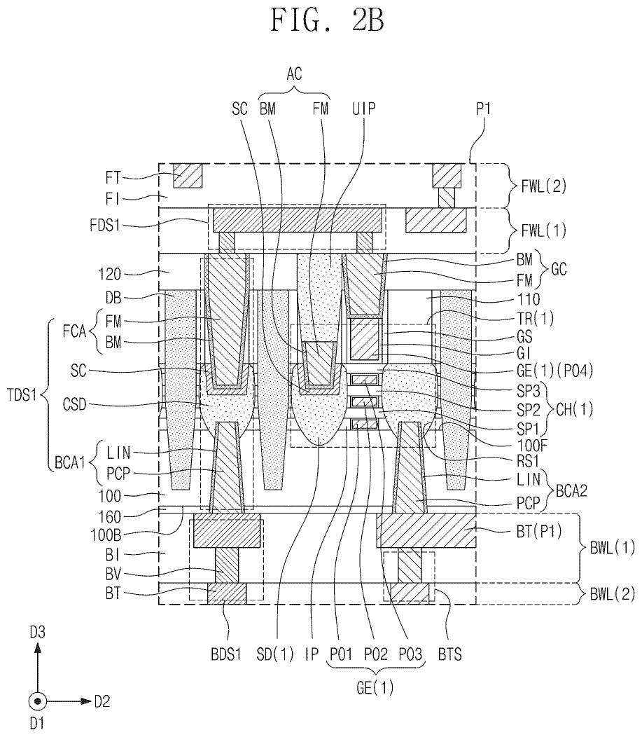

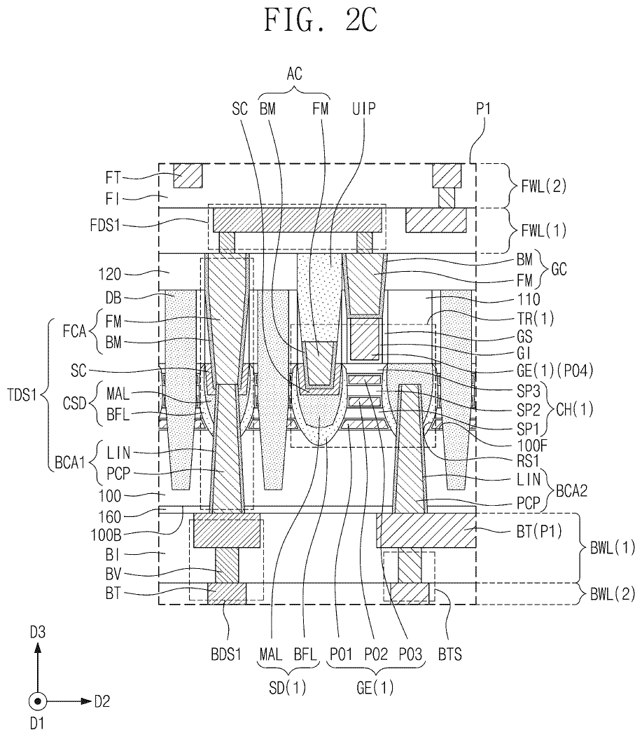

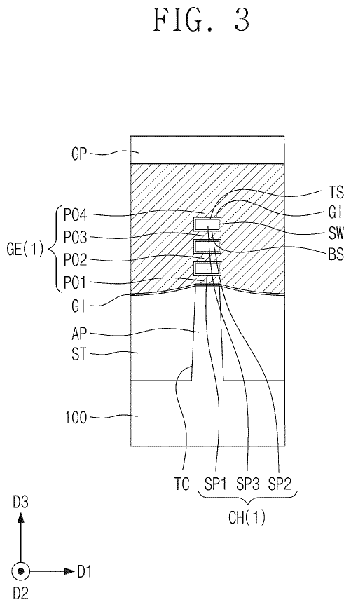

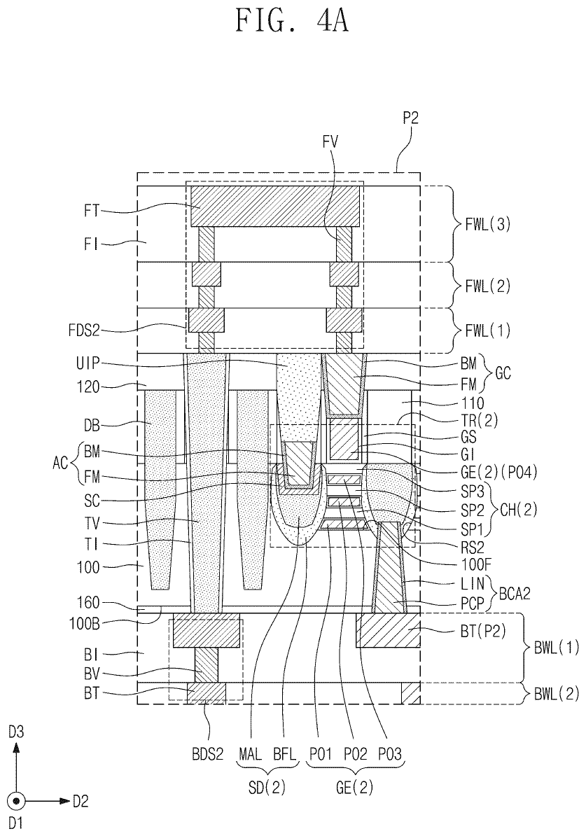

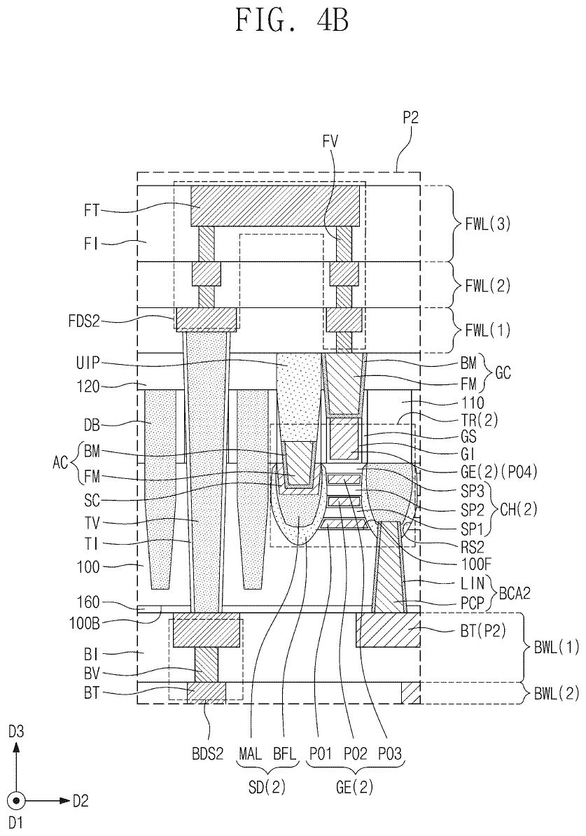

FIG. 1 is a sectional view illustrating a semiconductor device according to some embodiments of the inventive concept. FIGS. 2A to 2C are enlarged diagrams illustrating a portion ‘P1’ of FIG. 1. FIG. 3 is a sectional view illustrating a transistor according to some embodiments of the inventive concept. FIG. 3 is a sectional view of a gate electrode of the transistor of FIG. 1, taken in a length direction D1. FIGS. 4A and 4B are enlarged diagrams illustrating a portion ‘P2’ of FIG. 1.

Referring to FIGS. 1, 2A, and 4A, a semiconductor device 1000 according to the present embodiment may include a substrate 100. The substrate 100 may be a semiconductor substrate or a compound semiconductor substrate, which is formed of silicon, germanium, or silicon-germanium, or an insulating substrate, which is formed of an insulating material (e.g., silicon oxide). The substrate 100 may include a front surface 100F and a rear surface 100B, which are opposite to each other.

Transistors TR may be adjacent the front surface 100F of the substrate 100. As such, the transistors TR may be closer to front surface 100F than to rear surface 100B. Each of the transistors TR may include a gate electrode GE, source/drain patterns SD at both sides of the gate electrode GE, and a channel pattern CH between the source/drain patterns SD. The transistors TR may include a first transistor TR(1) and a second transistor TR(2). The first transistor TR(1) may include a first gate electrode GE(1), first source/drain patterns SD(1) adjacent to both sides of the first gate electrode GE(1), and a first channel pattern CH(1) between the first source/drain patterns SD(1). The second transistor TR(2) may include a second gate electrode GE(2), second source/drain patterns SD(2) adjacent to both sides of the second gate electrode GE(2), and a second channel pattern CH(2) between the second source/drain patterns SD(2).

The transistors TR may be provided in the form a multi-bridge channel FET (MBCFET), but the inventive concept is not limited to this example. For example, the transistors TR may be provided in the form of planar FET, FinFET, vertical FET, buried-channel array transistor (BCAT), or gate-all-around FET (GAAFET).

An active pattern AP may be defined by a trench TC, which is formed in an upper portion of the substrate 100. The active pattern AP may be a vertically-protruding portion of the substrate 100. In some embodiments, a plurality of active patterns AP may be provided. Some of the active patterns AP may be provided in a PMOSFET region, and others of the active patterns AP may be provided in an NMOSFET region. A device isolation layer ST may be provided to fill the trench TC. The device isolation layer ST may include a silicon oxide layer. The device isolation layer ST may not cover channel patterns CH, which will be described below.

Referring to FIG. 3, the channel pattern CH may be provided on one of the active patterns AP. The channel pattern CH may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (i.e., a third direction D3).

Referring to FIGS. 2A and 3, each of the first to third semiconductor patterns SP1, SP2, and SP3 may be formed of or include at least one of silicon (Si), germanium (Ge), or silicon-germanium (SiGe). For example, each of the first to third semiconductor patterns SP1, SP2, and SP3 may be formed of or include crystalline silicon. In some embodiments, each of the first to third semiconductor patterns SP1, SP2, and SP3 may be a nanosheet.

Referring to FIG. 2A, the first source/drain patterns SD(1) may be provided at both sides of the first channel pattern CH(1). A plurality of first recesses RS1 may be formed in an upper portion of the substrate 100. The first source/drain patterns SD(1) may be provided in the first recesses RS1, respectively. The first source/drain patterns SD(1) may be impurity regions of a first conductivity type (e.g., p-type). The stacked first to third semiconductor patterns SP1, SP2, and SP3 of the first channel pattern CH(1) may connect the first source/drain patterns SD(1) to each other.

Referring to FIG. 4A, the second source/drain patterns SD(2) may be provided at both sides of the second channel pattern CH(2). A plurality of second recesses RS2 may be formed in an upper portion of the substrate 100. The second source/drain patterns SD(2) may be provided in the second recesses RS2, respectively. The second source/drain patterns SD(2) may be impurity regions of the first conductivity type (e.g., p-type). The stacked first to third semiconductor patterns SP1, SP2, and SP3 of the second channel pattern CH(2) may connect the second source/drain patterns SD(2) to each other.

Referring to FIG. 3, the first gate electrode GE(1) may be provided to cross the first channel pattern CH(1) and extend in a first direction D1. Referring to FIG. 4A, the second gate electrode GE(2) may be provided to cross the second channel pattern CH(2) and extend in the first direction D1. The first and second gate electrodes GE(1) and GE(2) may be vertically overlapped with the first and second channel patterns CH(1) and CH(2), respectively.

Referring to FIG. 3, each of the first and second gate electrodes GE(1) and GE(2) may include a first inner electrode PO1 interposed between the active pattern AP and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring to FIG. 3, each of the first and second gate electrodes GE(1) and GE(2) may be provided on a top surface TS, a bottom surface BS, and opposite side surfaces SW of each of the first to third semiconductor patterns SP1, SP2, and SP3.

The first and second transistors TR(1) and TR(2) of FIGS. 2A, 2C, 4A, and 4B may have a PMOSFET structure. Here, each of the first and second source/drain patterns SD(1) and SD(2) may be formed of or include at least one of Si, SiGe, SiGeB, Ge, InSb, GaSb, or InGaSb.

In detail, referring to FIGS. 2A and 4A, the first and second source/drain patterns SD(1) and SD(2) may be epitaxial patterns, which are formed by a selective epitaxial growth (SEG) process. In some embodiments, a top surface of each of the first and second source/drain patterns SD(1) and SD(2) may be placed at substantially the same level as a top surface of the third semiconductor pattern SP3. Alternatively, the top surface of each of the first and second source/drain patterns SD(1) and SD(2) may be higher than the top surface of the third semiconductor pattern SP3.

The first source/drain patterns SD(1) may include a semiconductor material (e.g., SiGe) whose lattice constant is greater than that of the substrate 100. In this case, the first source/drain patterns SD(1) may be provided to exert a compressive stress to the first channel pattern CH(1) therebetween.

Each of the first source/drain patterns SD(1) may include a buffer layer BFL and a main layer MAL on the buffer layer BFL. Referring to FIGS. 2A and 4A, the buffer layer BFL may cover inner side surfaces of the first and second recesses RS1 and RS2. In some embodiments, the buffer layer BFL may have a substantially conformal thickness. In another embodiment, the buffer layer BFL may have a decreasing thickness in an upward direction. The buffer layer BFL may have a ‘U’ shape, due to the profile of the first and second recesses RS1 and RS2.

The main layer MAL may fill most of an unfilled region of the first and second recesses RS1 and RS2 covered with the buffer layer BFL. The volume of the main layer MAL may be larger than the volume of the buffer layer BFL. Each of the buffer and main layers BFL and MAL may be formed of or include silicon germanium (SiGe). In detail, the buffer layer BFL may contain a relatively low concentration of germanium (Ge). In another embodiment, the buffer layer BFL may contain only silicon (Si), without germanium (Ge). The germanium concentration of the buffer layer BFL may range from 0 at % to 10 at %.

The main layer MAL may contain a relatively high concentration of germanium (Ge). In some embodiments, the germanium concentration of the main layer MAL may range from 30 at % to 70 at %. The germanium concentration of the main layer MAL may increase as a distance in the third direction D3 increases. For example, the main layer MAL adjacent to the buffer layer BFL may have the germanium concentration of about 40 at %, but an upper portion of the main layer MAL may have the germanium concentration of about 60 at %.

Each of the buffer and main layers BFL and MAL may contain impurities (e.g., boron, gallium, or indium) that allow the first and second source/drain patterns SD(1) and SD(2) to have a p-type. The impurity concentration of each of the buffer and main layers BFL and MAL may range from 1E18 atom/cm³ to 5E22 atom/cm³. The impurity concentration of the main layer MAL may be higher than the impurity concentration of the buffer layer BFL.

The buffer layer BFL may prevent a stacking fault from occurring between the substrate 100 and the main layer MAL and between the first to third semiconductor patterns SP1, SP2, and SP3 and the main layer MAL. In the case where the stacking fault occurs, the channel resistance may be increased. The buffer layer BFL may protect the main layer MAL in a process of fabricating the semiconductor device 1000.

Alternatively, referring to FIG. 2B, the first transistor TR(1) may have an NMOSFET structure. The second transistor TR(2) may also have the NMOSFET structure. Here, each of the first and second source/drain patterns SD(1) and SD(2) may be formed of or include at least one of Si, SiP, SiC, SiPC, InP, GaAs, AlAs, InAs, InAlAs, or InGaAs.

As a detailed example, referring to FIG. 2B, each of the first and second source/drain patterns SD(1) and SD(2) may be formed of or include the same semiconductor material (e.g., Si) as the substrate 100. Each of the first and second source/drain patterns SD(1) and SD(2) may further contain n-type impurities (e.g., phosphorus, arsenic, or antimony). The impurity concentration of the first and second source/drain patterns SD(1) and SD(2) may range from 1E18 atom/cm³ to 5E22 atom/cm³.

Referring to FIG. 2B, in the case where the first transistor TR(1) and the second transistor TR(2) have the NMOSFET structure, inner spacers IP may be respectively interposed between the first to third inner electrodes PO1, PO2, and PO3 of the first gate electrode GE(1) and the first source/drain patterns SD(1). Although not shown, the inner spacers IP may be respectively interposed between the first to third inner electrodes PO1, PO2, and PO3 of the second gate electrode GE(2) and the second source/drain patterns SD(2). The inner spacers IP may be in direct contact with the first source/drain patterns SD(1). The inner spacers IP may be in direct contact with the second source/drain patterns SD(2). Each of the first to third inner electrodes PO1, PO2, and PO3 of the first gate electrode GE(1) may be spaced apart from the first source/drain patterns SD(1) by the inner spacer IP. Each of the first to third inner electrodes PO1, PO2, and PO3 of the second gate electrode GE(2) may be spaced apart from the second source/drain patterns SD(2) by the inner spacer IP.

Referring to FIGS. 2A and 4A, a pair of gate spacers GS may be respectively disposed on opposite side surfaces of the outer electrode PO4 of each of the first and second gate electrodes GE(1) and GE(2). The gate spacers GS may be extended along each of the first and second gate electrodes GE(1) and GE(2) and in the first direction D1. Top surfaces of the gate spacers GS may be higher than a top surface of each of the first and second gate electrodes GE(1) and GE(2). The top surfaces of the gate spacers GS may be coplanar with a top surface of a first interlayer insulating layer 110, which will be described below. The gate spacers GS may be formed of or include at least one of SiO₂, SiON, SiCN, SiCON, or SiN and may have a single- or multi-layered structure.

A gate capping pattern GP may be provided on each of the first and second gate electrodes GE(1) and GE(2). The gate capping pattern GP may be extended along each of the first and second gate electrodes GE(1) and GE(2) and in the first direction D1. The gate capping pattern GP may include a material having an etch selectivity with respect to first and second interlayer insulating layers 110 and 120 to be described below. In detail, the gate capping pattern GP may be formed of or include at least one of SiON, SiCN, SiCON, or SiN.

A gate insulating layer GI may be interposed between the first and second gate electrodes GE(1) and GE(2) and the first and second channel patterns CH(1) and CH(2). The gate insulating layer GI may cover the top surface TS, the bottom surface BS, and the opposite side surfaces SW of each of the first to third semiconductor patterns SP1, SP2, and SP3. Referring to FIG. 3, the gate insulating layer GI may cover a top surface of the device isolation layer ST below each of the first and second gate electrodes GE(1) and GE(2).

In some embodiments, the gate insulating layer GI may include a silicon oxide layer, a silicon oxynitride layer, and/or a high-k dielectric layer. The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

Each of the first and second gate electrodes GE(1) and GE(2) may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work-function metal, which can be used to adjust a threshold voltage of the transistor. By adjusting a thickness and composition of the first metal pattern, it may be possible to realize a transistor having a desired threshold voltage. For example, the first to third inner electrodes PO1, PO2, and PO3 of each of the first and second gate electrodes GE(1) and GE(2) may be composed of the first metal pattern or the work-function metal.

The first metal pattern may include a metal nitride layer. For example, the first metal pattern may include a layer that is composed of at least one metallic material, which is selected from the group consisting of titanium (Ti), tantalum (Ta), aluminum (Al), tungsten (W) and molybdenum (Mo), and nitrogen (N). In some embodiments, the first metal pattern may further include carbon (C). The first metal pattern may include a plurality of work function metal layers which are stacked.

The second metal pattern may be formed of or include a metallic material whose resistance is lower than the first metal pattern. For example, the second metal pattern may be formed of or include at least one metallic material, which is selected from the group consisting of tungsten (W), aluminum (Al), titanium (Ti), and tantalum (Ta). For example, the outer electrode PO4 of each of the first and second gate electrodes GE(1) and GE(2) may include the first metal pattern and the second metal pattern on the first metal pattern.

A first interlayer insulating layer 110 may be provided on the substrate 100. The first interlayer insulating layer 110 may cover the gate spacers GS and the first and second source/drain patterns SD(1) and SD(2). A top surface of the first interlayer insulating layer 110 may be substantially coplanar with a top surface of the gate capping pattern GP and a top surface of the gate spacer GS. A second interlayer insulating layer 120 may be formed on the first interlayer insulating layer 110 to cover the gate capping pattern GP. In some embodiments, each of the first and second interlayer insulating layers 110 and 120 may include a silicon oxide layer.

Division structures DB may be provided to separate cell regions from each other. The cell regions may be regions which are used for various logic cells (e.g., a single height cell (SHC) or a double height cell (DHC)) or for tap cells. The logic cell may mean a logic device (e.g., AND, OR, XOR, XNOR, inverter, and so forth), which is configured to execute a specific function. In other words, the logic cell may include transistors constituting the logic device and interconnection lines connecting the transistors to each other. The tap cell may not include the logic device, unlike the logic cell. That is, the tap cell may be configured to apply a voltage to the power line but may be just a dummy cell that does not serve as a circuit element.

The division structure DB may be extended in the first direction D1 and parallel to the gate electrodes GE(1) and GE(2). A pitch between the division structure DB and the gate electrodes GE(1) and GE(2), which are adjacent to each other, may be equal to a pitch between the gate electrodes GE(1) and GE(2).

The division structure DB may be provided to penetrate the first interlayer insulating layer 110 and may be extended into the substrate 100. The division structure DB may electrically separate an active region of one cell region from an active region of another cell region adjacent thereto.

Referring to FIGS. 1 and 2A, an active contact AC, which is connected to at least one of the source/drain patterns SD, may be provided. When viewed in a plan view, the active contact AC may be a bar-shaped pattern that is extended in the first direction D1. The active contact AC may be provided to penetrate the first and second interlayer insulating layers 110 and 120.

The active contact AC may be a self-aligned contact. For example, the active contact AC may be formed by a self-alignment process using the gate capping pattern GP and the gate spacer GS. For example, the active contact AC may cover at least a portion of the side surface of the gate spacer GS.

A metal-semiconductor compound layer SC (e.g., a silicide layer) may be interposed between the active contact AC and one of the source/drain patterns SD. The active contact AC may be electrically connected to one of the source/drain patterns SD through the metal-semiconductor compound layer SC. For example, the metal-semiconductor compound layer SC may be formed of or include at least one of titanium silicide, tantalum silicide, tungsten silicide, nickel silicide, or cobalt silicide.

Gate contacts GC may be provided to penetrate the second interlayer insulating layer 120 and the gate capping pattern GP and may be electrically connected to the gate electrodes GE, respectively. The gate contact GC may be freely disposed on the gate electrode GE, without any restrictions on its position.

An upper portion of the active contact AC adjacent to the gate contact GC may be filled with an upper insulating pattern UIP. A bottom surface of the upper insulating pattern UIP may be lower than a bottom surface of the gate contact GC. In other words, a top surface of the active contact AC adjacent to the gate contact GC may be formed at a level, which is lower than the bottom surface of the gate contact GC, by the upper insulating pattern UIP. Accordingly, it may be possible to prevent the gate contact GC and the active contact AC, which are adjacent to each other, from being in contact with each other and thereby to prevent a short circuit issue from occurring therebetween.

Each of the active and gate contacts AC and GC may include a conductive pattern FM and a barrier pattern BM enclosing the conductive pattern FM. For example, the conductive pattern FM may be formed of or include at least one of metallic materials (e.g., aluminum, copper, tungsten, molybdenum, or cobalt). The barrier pattern BM may cover side surfaces and a bottom surface of the conductive pattern FM. The barrier pattern BM may include a metal layer and a metal nitride layer. The metal layer may be formed of or include at least one of titanium, tantalum, tungsten, nickel, cobalt, and platinum. The metal nitride layer may be formed of or include at least one of titanium nitride (TiN), tantalum nitride (TaN), tungsten nitride (WN), nickel nitride (NiN), cobalt nitride (CON), or platinum nitride (PtN).

Referring to FIGS. 1, 2A, and 4A, front-side interconnection layers FWL may be sequentially stacked on the second interlayer insulating layer 120. The front-side interconnection layers FWL may include first to J-th front-side interconnection layers FWL(1) to FWL(J). Each of the front-side interconnection layers FWL may include a front-side insulating layer FI, and front-side vias FV and front-side lines FT, which are disposed in the front-side insulating layer FI. The number J may be a natural number greater than or equal to 3.

The front-side insulating layer FI may be formed of or include at least one of SiO₂, SiN, SION, SiCN, or SiOCH and may have a single- or multi-layered structure. Each of the front-side vias FV and the front-side lines FT may be formed of or include at least one of metallic materials (e.g., tungsten, copper, aluminum, titanium, and tantalum).

The front-side lines FT, which are included in the odd-numbered ones (e.g., FWL (1), FWL (3), . . . ) of the front-side interconnection layers FWL, may be extended in a second direction D2. The front-side lines FT, which are included in the even-numbered ones (e.g., FWL (2), FWL (4), . . . ) of the front-side interconnection layers FWL, may be extended in the first direction D1 crossing the second direction D2. Some of the front-side lines and vias FT and FV may be used to apply or transmit an electrical signal to the gate contact GC and the active contact AC.

The smaller the distance to the front surface 100F of the substrate 100, the smaller the width, height, pitch, and/or density per unit area of the front-side lines FT. The smaller the distance to the front surface 100F of the substrate 100, the smaller the width, height, pitch, and/or density per unit area of the front-side vias FV.

The first transistor TR(1), the second transistor TR(2), and some of the front-side lines FT and some of the the front-side vias FV may constitute a part of a logic circuit, such as flip-flop, inverter, AND, OR, XOR, XNOR, NAND, and NOR circuits. The first transistor TR(1) and the second transistor TR(2) (in particular, the first and second gate electrodes GE(1) and GE(2) of the first and second transistors TR(1) and TR(2)) may correspond to testing points, which are chosen to detect a failure in a process of testing the semiconductor device.

A bonding insulating layer 210 may be disposed on the J-th front-side interconnection layer FWL(J). The bonding insulating layer 210 may be formed of or include at least one of SiO₂, SiN, or SiCN and may have a single- or multi-layered structure. A supporting substrate 200 may be disposed on the bonding insulating layer 210. The supporting substrate 200 may be a silicon substrate or an insulating substrate. The supporting substrate 200 may be omitted. The bonding insulating layer 210 may be referred to as a ‘passivation layer’. The supporting substrate 200 and the bonding insulating layer 210 may be transparent enough to allow light to pass through.

Referring to FIGS. 1, 2A, and 4A, the rear surface 100B of the substrate 100 may be covered with a lower insulating layer 160. The lower insulating layer 160 may be formed of or include at least one of SiO₂, SiN, or SiON and may have a single- or multi-layered structure. Back-side interconnection layers BWL may be stacked below the lower insulating layer 160. The back-side interconnection layers BWL may include the first to K-th back-side interconnection layers BWL(1) to BWL(K). The number K may be a natural number greater than or equal to 2. The number K may be less than the number J.

Each of the back-side interconnection layers BWL may include a back-side insulating layer BI, and back-side vias BV and back-side lines BT, which are disposed in the back-side insulating layer BI. The back-side insulating layer BI may be formed of or include at least one of SiO₂, SiN, SiON, SiCN, or SiOCH and may have a single- or multi-layered structure. The lowermost one of the back-side insulating layers BI(B) may be referred to as a passivation layer. Each of the back-side vias and lines BV and BT may be formed of or include at least one of metallic materials (e.g., tungsten, copper, aluminum, titanium, and tantalum).

The back-side lines BT, which are included in the odd-numbered ones (e.g., BWL(1), BWL(3), and . . . ) of the back-side interconnection layers BWL, may be extended in the second direction D2. The back-side lines BT, which are included in the even-numbered ones (e.g., BWL(2), BWL(4), and . . . ) of the back-side interconnection layers BWL, may be extended in the first direction D1 crossing the second direction D2. Some of the back-side vias and lines BV and BT may constitute a back-side power network. Some of the back-side lines and vias BT and BV may apply a source voltage or a drain voltage to at least one of the source/drain patterns SD.

The uppermost ones BT(P1), BT(P2), and BT(U) of the back-side lines BT may have a width, height, and/or pitch that are smaller than those of the lowermost ones BT(B1) and BT(B2). Each of the lowermost ones BT(B1) and BT(B2) of the back-side lines BT may be referred to as a ‘bonding pad’.

Referring to FIGS. 1, 2A, and 4A, some of the uppermost ones BT(P1), BT(P2), and BT(U) of the back-side lines BT may be the power lines BT(P1) and BT(P2). Second back-side contacts BCA2 may be provided to penetrate the substrate 100 and to connect the power lines BT(P1) and BT(P2) to at least one of the source/drain patterns SD. For example, one of the second back-side contacts BCA2 may be provided to penetrate the substrate 100 and to connect one of the power lines BT(P1) to one of the first source/drain patterns SD(1) of the first transistor TR(1). Thus, a drain voltage VDD or a source voltage VSS may be applied to one of the first source/drain patterns SD(1). In some embodiments, one of the second back-side contacts BCA2 may be provided to penetrate the substrate 100 and to connect one of the power lines BT(P2) to one of the second source/drain patterns SD(2) of the second transistor TR(2). Accordingly, the drain voltage VDD or the source voltage VSS may be applied to one of the second source/drain patterns SD(2).

The second back-side contacts BCA2 may have a conductive pillar shape. Each of the back-side contacts BCA1 and BCA2 may include a contact PCP and a liner LIN, which is provided to enclose at least a side surface of the contact PCP. The contact PCP may be formed of or include at least one of metallic materials (e.g., tungsten, molybdenum, ruthenium, cobalt, aluminum, or copper). The liner LIN may be formed of or include at least one of silicon-based insulating materials (e.g., SiO, SiN, SiOC, or SiOCN).

The first gate electrode GE(1) of the first transistor TR(1) may be connected to a first front-side detection structure FDS1, a first penetration detection structure TDS1, and a first back-side detection structure BDS1. The second gate electrode GE(2) of the second transistor TR(2) may be connected to a second front-side detection structure FDS2, a penetration via TV, and a second back-side detection structure BDS2.

Some of the front-side lines FT and some of the front-side vias FV may constitute the first and second front-side detection structures FDS1 and FDS2, which are spaced apart from each other.

Referring to FIGS. 1 and 2A, the first front-side detection structure FDS1 may be placed in the first front-side interconnection layer FWL(1). When viewed in a sectional view, the first front-side detection structure FDS1 may include one front-side line FT and two front-side vias FV. An upper end of the first front-side detection structure FDS1 may be placed at a first level LV1.

An end portion of the first front-side detection structure FDS1 may be in contact with the gate contact GC on the first gate electrode GE(1). Another end portion of the first front-side detection structure FDS1 may be connected to the first penetration detection structure TDS1 penetrating the second interlayer insulating layer 120, the first interlayer insulating layer 110, and the substrate 100. The first penetration detection structure TDS1 may be disposed between adjacent ones of the division structures DB.

Referring to FIGS. 1 and 2A, the first penetration detection structure TDS1 may include a front-side contact FCA, which is provided to penetrate the second interlayer insulating layer 120 and the first interlayer insulating layer 110, and the first back-side contact BCA1, which is provided to penetrate the substrate 100.

As shown in FIGS. 2A and 2B, the first penetration detection structure TDS1 may further include a connection conductive pattern CSD interposed between the front-side contact FCA and the first back-side contact BCA1. The first penetration detection structure TDS1 may further include the metal-semiconductor compound layer SC interposed between the connection conductive pattern CSD and the front-side contact FCA.

In some embodiments, referring to FIG. 2C, the first back-side contact BCA1 may penetrate the connection conductive pattern CSD and the metal-semiconductor compound layer SC and may be in contact with the front-side contact FCA.

The front-side contact FCA may have a similar structure to the active contact AC. The front-side contact FCA may include the conductive pattern FM and the barrier pattern BM enclosing the conductive pattern FM.

The first back-side contact BCA1 may have a similar structure to the second back-side contacts BCA2. The first back-side contact BCA1 may include the contact PCP and the liner LIN, which is provided to enclose at least a side surface of the contact PCP. A level of an upper end of the first back-side contact BCA1 may be equal to a level of an upper end of the second back-side contacts BCA2.

The connection conductive pattern CSD may have the same or similar structure as the source/drain patterns SD. The connection conductive pattern CSD may be doped with the same dopants as the source/drain patterns SD. The connection conductive pattern CSD may include the buffer layer BFL and the main layer MAL on the buffer layer BFL, as shown in FIG. 2A. The connection conductive pattern CSD may be doped with p-type impurities or dopants. Alternatively, the connection conductive pattern CSD may be formed of or include at least one of Si, SiP, SiC, SiPC, InP, GaAs, AlAs, InAs, InAlAs, or InGaAs, as shown in FIG. 2B. The connection conductive pattern CSD may be doped with n-type impurities (e.g., phosphorus, arsenic, or antimony).

Referring to FIGS. 1 and 4A, the second front-side detection structure FDS2 may be disposed in the first to third front-side interconnection layers FWL(1) to FWL(3). The second front-side detection structure FDS2 may include the front-side lines FT and the front-side vias FV. An upper end of the second front-side detection structure FDS2 may be placed at a second level LV2. The second level LV2 may be different from (e.g., higher than) the first level LV1.

The second front-side detection structure FDS2 may have an inverted ‘U’-shaped structure, when viewed in a sectional view. An end portion of the second front-side detection structure FDS2 may be in contact with the gate contact GC on the second gate electrode GE(2). Another end portion of the second front-side detection structure FDS2 may be in contact with the penetration via TV.

Referring to FIG. 4A, the penetration via TV may be disposed between adjacent ones of the division structures DB. The penetration via TV may be provided to penetrate the second interlayer insulating layer 120, the first interlayer insulating layer 110, the substrate 100, and the lower insulating layer 160. The penetration via TV may further penetrate the front-side insulating layer FI of the first front-side interconnection layer FWL(1), as shown in FIG. 4B. The penetration via TV may be formed of or include at least one of metallic materials (e.g., tungsten, molybdenum, ruthenium, cobalt, aluminum, and copper). A side surface of the penetration via TV may be covered with a via insulating layer TI. The via insulating layer TI may be formed of or include at least one of SiO₂ or SiN.

Referring to FIG. 1, the back-side lines BT and the back-side vias BV may constitute the first back-side detection structure BDS1, the second back-side detection structure BDS2, and back-side interconnection structures BTS. The first back-side detection structure BDS1 may be adjacent rear surface 100B. As such, first back-side detection structure BDS1 may be closer to rear surface 100B than to front surface 100F. The first back-side detection structure BDS1 may be connected to the first penetration detection structure TDS1. The second back-side detection structure BDS2 may be connected to the penetration via TV. The back-side interconnection structures BTS may be connected to the power lines BT(P1) and BT(P2).

A lower end of the first back-side detection structure BDS1 may be placed at a third level LV3. A lower end of the second back-side detection structure BDS2 may be placed at a fourth level LV4. A lower end of at least one of the back-side interconnection structures BTS may be placed at a fifth level LV5. The third to fifth levels LV3 to LV5 may be lower than the first and second levels LV1 and LV2. The third to fifth levels LV3 to LV5 may be substantially equal to each other. A vertical length of the first back-side detection structure BDS1 may be equal to a vertical length of the second back-side detection structure BDS2.

First outer connection terminals OB1 may be provided to penetrate the lowermost one of the back-side insulating layers BI(B) and may be bonded to the first bonding pads BT(B1) of the back-side interconnection structures BTS. Second outer connection terminals OB2 may be provided to penetrate the lowermost one of the back-side insulating layers BI(B) and may be bonded to the second bonding pads BT(B2) of the first and second back-side detection structures BDS1 and BDS2. Each of the first and second outer connection terminals OB1 and OB2 may include a conductive bump, a conductive pillar, and/or a solder ball. The second outer connection terminals OB2 may be used as a test signal port of the semiconductor device 1000.

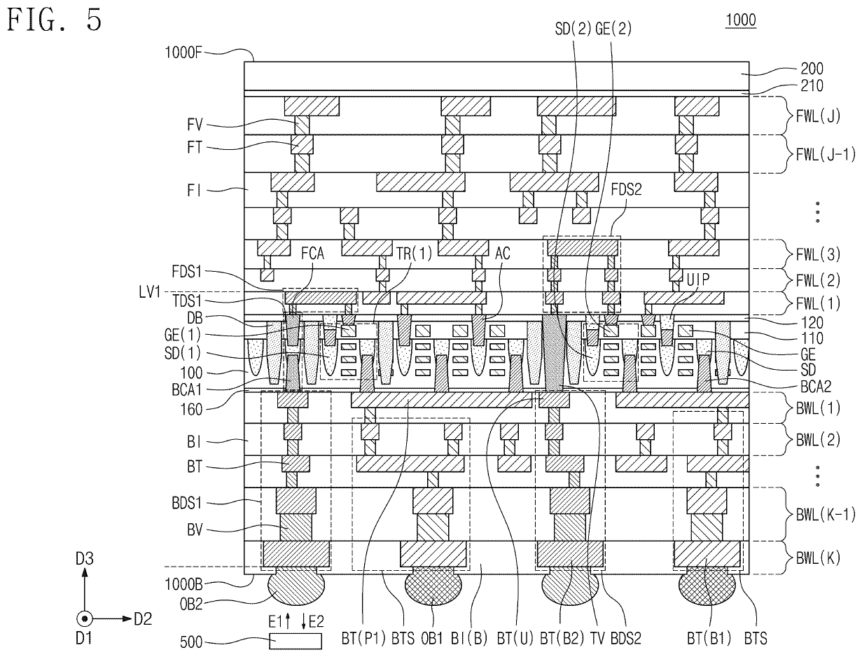

FIG. 5 is a schematic diagram illustrating a method of detecting a failure in the semiconductor device of FIG. 1.

Referring to FIG. 5, the semiconductor device 1000 described with reference to FIGS. 1 to 4B may be fabricated. The semiconductor device 1000 may be fabricated using a conventional fabrication process. However, the connection conductive pattern CSD and the source/drain patterns SD may be formed at the same time. The front-side contact FCA and the active contact AC may be formed at the same time. The first back-side contacts BCA1 and the second back-side contacts BCA2 may be formed at the same time. The first and second back-side detection structures BDS1 and BDS2 and the back-side interconnection structures BTS may be formed at the same time.

In the method of detecting a failure in a semiconductor device according to some embodiments of the inventive concept, an electron-beam generating and sensing device 500 may be placed to be adjacent to a rear surface 1000B of the semiconductor device 1000. Then, at least one of the second outer connection terminals OB2 may be irradiated with a first electron beam E1, and a second electron beam E2, which is reflected or emitted, may be sensed. In the case where there is a failure in at least one of logic circuits composed of the first and second transistors TR(1) and TR(2), the characteristics (e.g., phase shift, amplitude variation of secondary electrons, energy spectrum variation, etc.) of the second electron beam E2 may differ from those of the first electron beam E1. By using this method, it may be possible to precisely find a failure position of the semiconductor device.

As an example, the electrons in the first electron beam E1, which is irradiated onto the second outer connection terminal OB2 connected to the first back-side detection structure BDS1, may be transferred to the first gate electrode GE(1) through the first back-side detection structure BDS1, the first penetration detection structure TDS1, and the first front-side detection structure FDS1, and depending on whether the first transistor TR(1) has a failure or not, at least a portion of the electrons may be emitted to the outside of the second outer connection terminal OB2 through the first front-side detection structure FDS1, the first penetration detection structure TDS1, and the first back-side detection structure BDS1 to form the second electron beam E2. The characteristics (e.g., reflectivity or wavelength) of the second electron beam E2 may be analyzed to determine whether the first transistor TR(1) has a failure.

The semiconductor device according to some embodiments of the inventive concept may include the detection structures FDS1, FDS2, TDS1, BDS1, and BDS2, which are connected to testing points for detecting a failure in a test process. That is, the first gate electrode GE(1) of the first transistor TR(1) may be connected to the first front-side detection structure FDS1, the first penetration detection structure TDS1, the first back-side detection structure BDS1, and one of the second outer connection terminals OB2, and thus, a test signal may be applied to the first gate electrode GE(1) from an outside of the rear surface 1000B of the semiconductor device 1000. Similarly, the second gate electrode GE(2) of the second transistor TR(2) may be connected to the second front-side detection structure FDS2, the penetration via TV, the second back-side detection structure BDS2, and another one of the second outer connection terminals OB2, and thus, a test signal may be applied to the second gate electrode GE(2) from the outside of the rear surface 1000B of the semiconductor device 1000. Thus, the semiconductor device may have a structure that can be easily tested.

Even when the first front-side detection structure FDS1 connected to the first gate electrode GE(1) is placed at a different level from the second front-side detection structure FDS2 connected to the second gate electrode GE(2), due to the back-side detection structures BDS1 and BDS2, the test signals may be applied to the first and second gate electrodes GE(1) and GE(2) from the outside of the rear surface 1000B of the semiconductor device 1000. Accordingly, to test the semiconductor device 1000, it may be unnecessary to form holes, which pass through a front surface 1000F of the semiconductor device 1000 and have different depths, and thus, it may be possible to perform the test process in a simple and easy manner.

In addition, since the back-side detection structures BDS1 and BDS2 are disposed in the back-side interconnection layers BWL having a lower interconnection density than the front-side interconnection layers FWL, an interconnection routing step for placing back-side detection structures may be easily performed in a process of designing the semiconductor device.

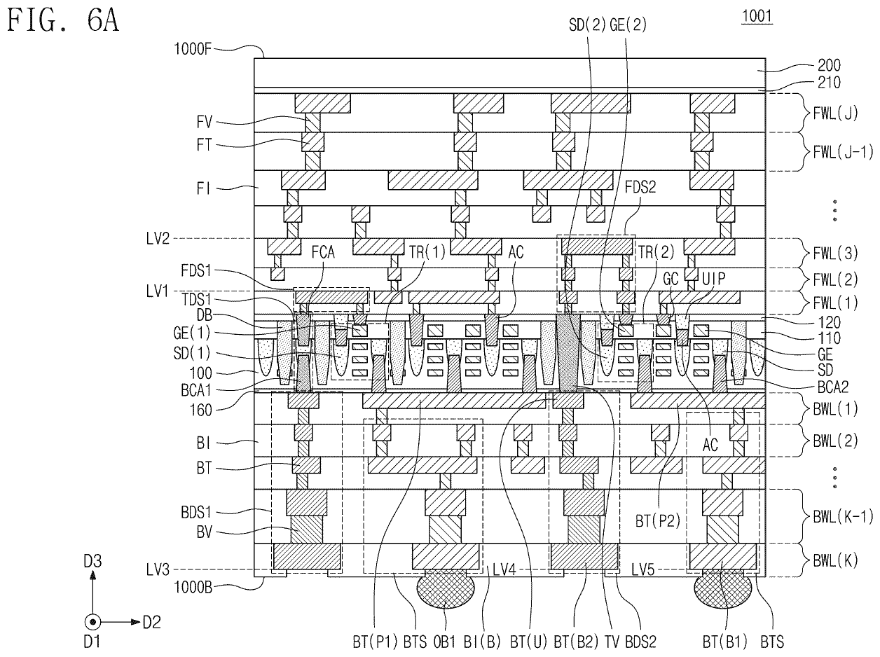

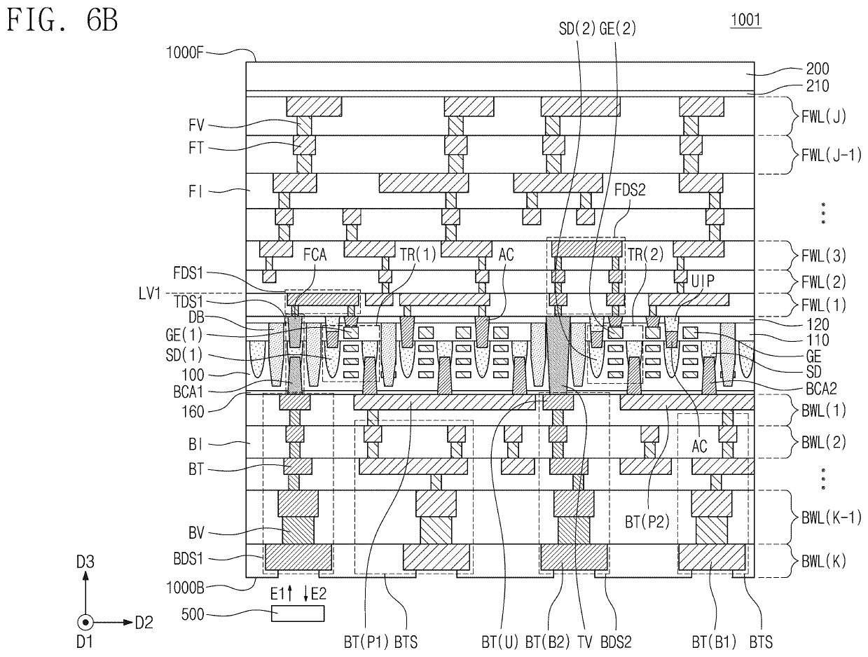

FIG. 6A is a sectional view illustrating a semiconductor device according to some embodiments of the inventive concept. FIG. 6B is a schematic diagram illustrating a method of detecting a failure in the semiconductor device of FIG. 6A.

Referring to FIG. 6A, a semiconductor device 1001 in the present embodiment may not include the second outer connection terminals OB2 of FIG. 1. At least a portion of bottom surfaces of the second bonding pads BT(B2) may not be covered with the lowermost back-side insulating layer BI(B) and may be exposed to the outside. The second bonding pads BT(B2) may be used as a test signal port of the semiconductor device 1001.

Referring to FIG. 6B, in the method of detecting a failure in a semiconductor device according to some embodiments of the inventive concept, the electron-beam generating and sensing device 500 may be placed to be adjacent to the rear surface 1000B of the semiconductor device 1001. Then, at least one of the second bonding pads BT(B2) may be irradiated with the first electron beam E1, and the second electron beam E2, which is reflected or emitted, may be sensed. By using this method, it may be possible to precisely find a failure position of the semiconductor device. A process of bonding the first outer connection terminals OB1 of FIG. 6A may be performed after the test process.

The semiconductor device according to another embodiment of the inventive concept may have a structure, which has substantially the same as that in FIG. 6A, but in which the bottom surfaces of the second bonding pads BT(B2) are fully covered with the lowermost back-side insulating layer BI(B). In this case, a portion of the lowermost back-side insulating layer BI(B) may be removed to expose the bottom surfaces of the second bonding pads BT(B2), before a test process of detecting a failure in the semiconductor device.

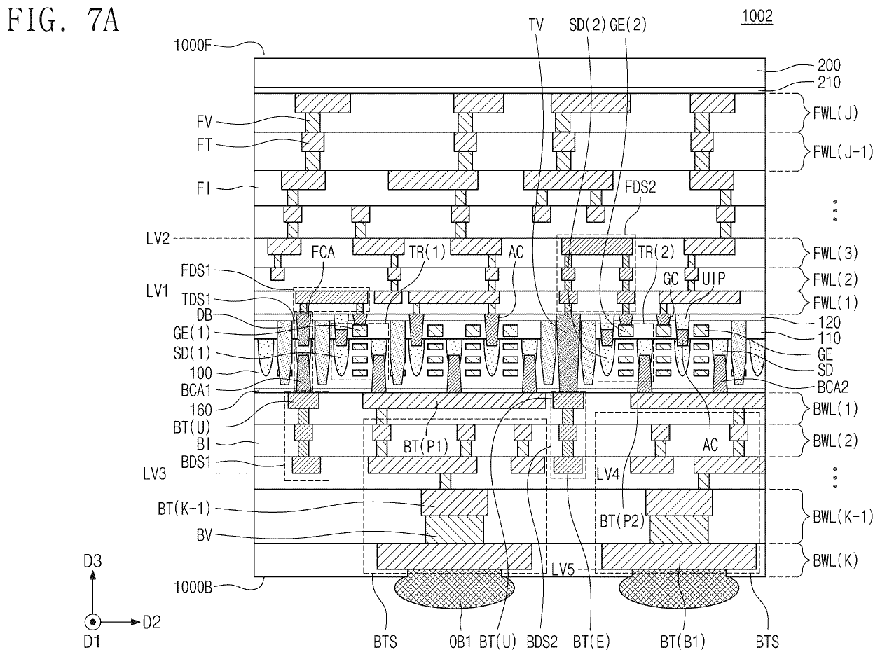

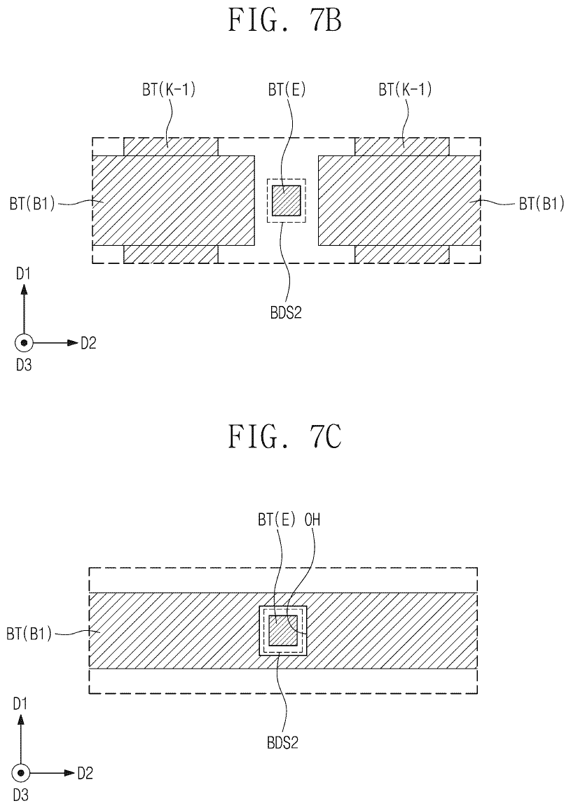

FIG. 7A is a sectional view illustrating a semiconductor device according to some embodiments of the inventive concept.

Referring to FIG. 7A, a semiconductor device 1002 in the present embodiment may not include the second outer connection terminals OB2 and the second bonding pads BT(B2) of FIG. 1. The back-side lines BT may further include a (K−1)-th back-side line BT(K−1) connected to the first bonding pads BT(B1). The (K−1)-th back-side line BT(K−1) may be included in the (K−1)-th back-side interconnection layer BWL(K−1). In the semiconductor device 1002 according to the present embodiment, the third level LV3 of the lower end of the first back-side detection structure BDS1 may be equal to the fourth level LV4 of the lower end of the second back-side detection structure BDS2 and may be higher than the fifth level LV5 of the lower end of the back-side interconnection structure BTS. In other words, the lowermost back-side line BT(E) for detection, which is the lowermost one of the back-side lines BT constituting the first and second back-side detection structures BDS1 and BDS2, may be placed between the first back-side interconnection layer BWL(1) and the K-th back-side interconnection layer BWL(K). The lowermost back-side line BT(E) for detection may be used as a test signal port of the semiconductor device 1001.

FIGS. 7B and 7C are plan views illustrating a portion of the semiconductor device of FIG. 7A.

Referring to FIGS. 7A and 7B, the lowermost back-side line BT(E) for detection may not be vertically overlapped with the first bonding pads BT(B1) and the (K−1)-th back-side line BT(K−1). When viewed in a plan view, the lowermost back-side line BT(E) for detection may be located between the first bonding pads BT(B1).

Alternatively, referring to FIGS. 7A and 7C, the first bonding pads BT(B1) may be extended in the second direction D2 and may be connected to each other to form an interconnection line applied with a power voltage. The first bonding pad BT(B1) may have a hole OH. When viewed in a plan view, the lowermost back-side line BT(E) for detection may be vertically overlapped with the hole OH.

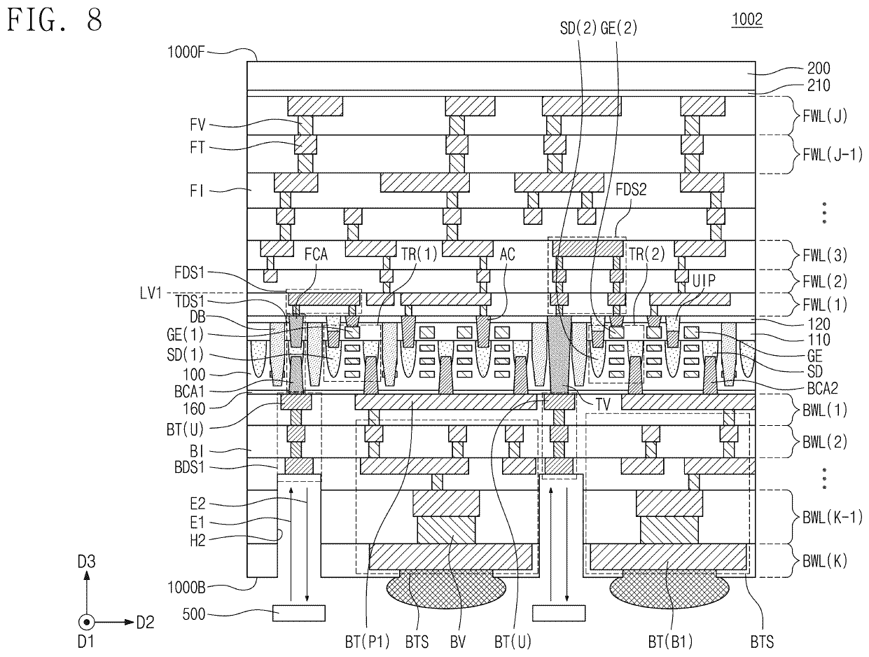

FIG. 8 is a schematic diagram illustrating a method of detecting a failure in the semiconductor device of FIG. 7A.

Referring to FIG. 8, in the method of detecting a failure in a semiconductor device according to some embodiments of the inventive concept, trenches H2 may be formed in the rear surface 1000B of the semiconductor device 1002 of FIG. 7A to expose the lowermost back-side line BT(E) for detection. Here, since the third level LV3 of the lower end of the first back-side detection structure BDS1 is equal to the fourth level LV4 of the lower end of the second back-side detection structure BDS2, the trenches H2 may be formed to have the same depth. In this case, the trenches H2 may be more easily formed compared to forming trenches with different depths. That is, before testing the semiconductor device, a decapsulating process may be easily performed.

The electron-beam generating and sensing device 500 may be placed to be adjacent to the rear surface 1000B of the semiconductor device 1001. Then, the electron-beam generating and sensing device 500 may be configured to irradiate at least one of the lowermost back-side lines BT(E) for detection with the first electron beam E1 through the trenches H2 and to sense the second electron beam E2 reflected or emitted from the lowermost back-side lines BT(E) for detection. By using this method, it may be possible to precisely find a failure position of the semiconductor device.

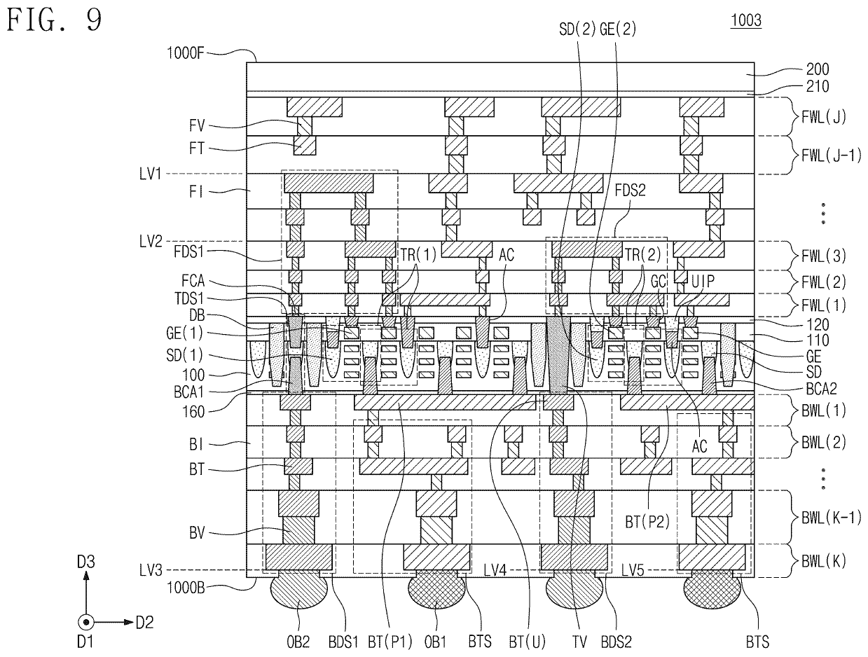

FIG. 9 is a sectional view illustrating a semiconductor device according to some embodiments of the inventive concept.

Referring to FIG. 9, in a semiconductor device 1003 according to the present embodiment, the first front-side detection structure FDS1 may connect the first gate electrodes GE(1) of two adjacent ones of the first transistors TR(1) to the first penetration detection structure TDS1. The second front-side detection structure FDS2 may connect the second gate electrodes GE(2) of two adjacent ones of the second transistors TR(2) to the penetration via TV. The first level LV1 of the upper end of the first front-side detection structure FDS1 may be higher than the second level LV2 of the upper end of the second front-side detection structure FDS2. In the present embodiment, the number of the transistors TR, which are connected to each of the first and second front-side detection structures FDS1 and FDS2, is not limited to 2 and is equal to or greater than 3. In addition, each of the first and second front-side detection structures FDS1 and FDS2 may be connected to at least one of the source/drain patterns SD of the transistors TR. Except for the afore-described features, the semiconductor device may have substantially the same features as described with reference to FIGS. 1 to 7C.

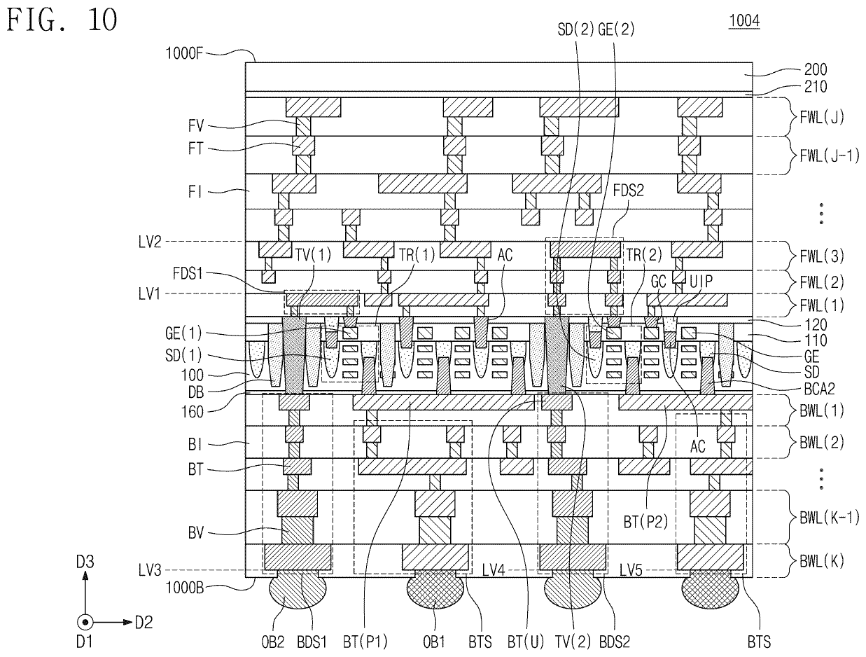

FIG. 10 is a sectional view illustrating a semiconductor device according to some embodiments of the inventive concept.

Referring to FIG. 10, in a semiconductor device 1004 according to the present embodiment, the first front-side detection structure FDS1 may be connected to the first back-side detection structure BDS1 through the first penetration via TV (1). The second front-side detection structure FDS2 may be connected to the second back-side detection structure BDS2 through the second penetration via TV (2). Except for the afore-described features, the semiconductor device may have substantially the same features as described with reference to FIGS. 1 to 7C.

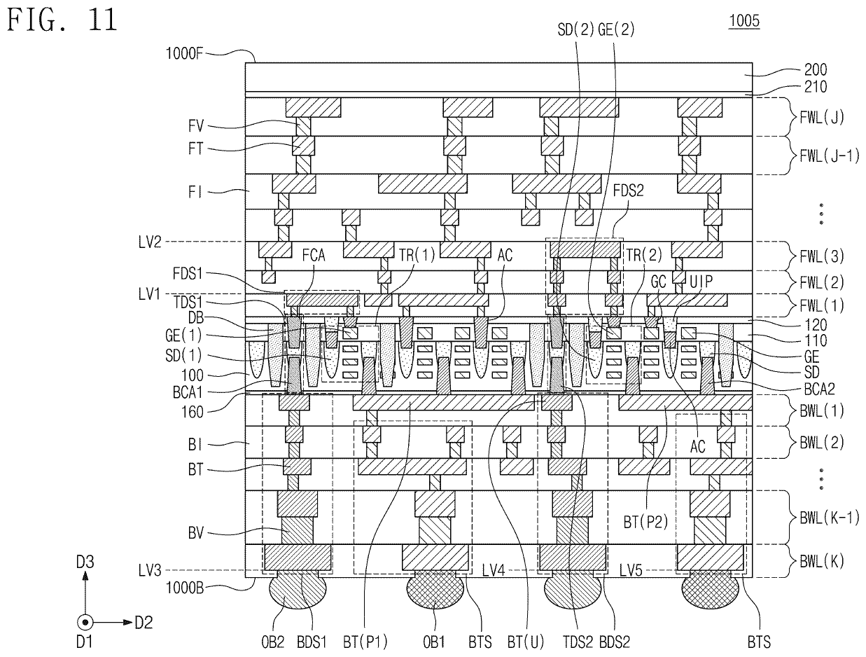

FIG. 11 is a sectional view illustrating a semiconductor device according to some embodiments of the inventive concept.

Referring to FIG. 11, in a semiconductor device 1005 according to the present embodiment, the first front-side detection structure FDS1 may be connected to the first back-side detection structure BDS1 through the first penetration detection structure TDS1. The second front-side detection structure FDS2 may be connected to the second back-side detection structure BDS2 through a second penetration detection structure TDS2. Except for the afore-described features, the semiconductor device may have substantially the same features as described with reference to FIGS. 1 to 7C. The second penetration detection structure TDS2 may have the same or similar structure as the first penetration detection structure TDS1. Except for the afore-described features, the semiconductor device may have substantially the same features as described with reference to FIGS. 1 to 7C.

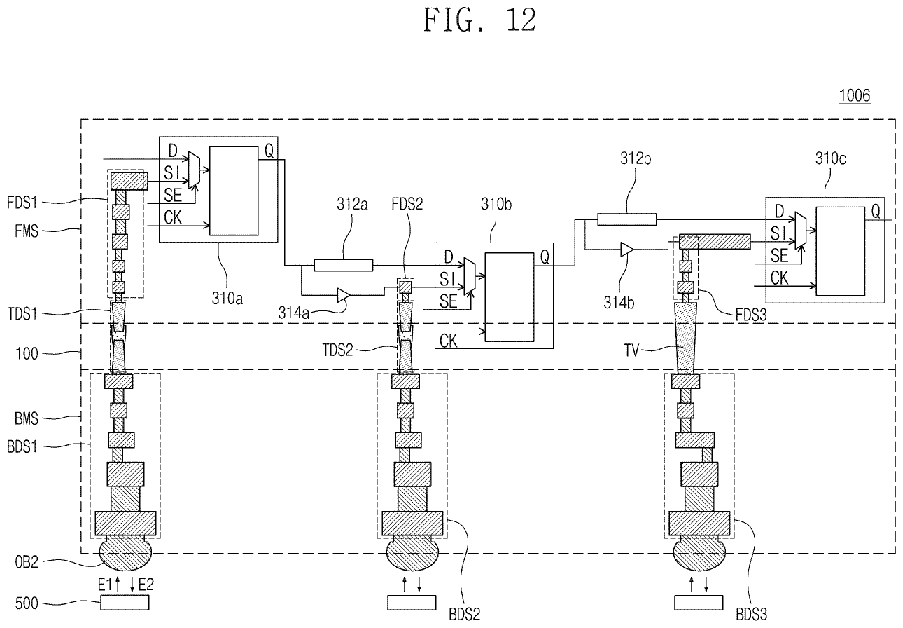

FIG. 12 is a conceptual diagram illustrating a semiconductor device according to some embodiments of the inventive concept.

Referring to FIG. 12, a semiconductor device 1006 in the present embodiment may include the substrate 100, an upper structure FMS on the substrate 100, and a lower structure BMS below the substrate 100. The upper structure FMS may include flip-flop circuits 310a, 310b, and 310c, buffers 314a and 314b, and cells 312a and 312b, which are connected to each other. The flip-flop circuits 310a, 310b, and 310c, the buffers 314a and 314b, and the cells 312a and 312b may constitute a scan chain. Each of the cells 312a and 312b may be a logic cell and/or a memory cell. Each of the buffers 314a and 314b may include an inverter.

Each of the flip-flop circuits 310a, 310b, and 310c may include a test input terminal SI, to which a test signal is input, an enable signal input terminal for MUX (SE), a functional input terminal D, a clock cycle signal input terminal CK, and an output terminal Q. Each of the flip-flop circuits 310a, 310b, and 310c may include at least one of the first and second transistors TR(1) and TR(2), the front-side lines FT, and the front-side vias FV described with reference to FIGS. 1 to 11. The test input terminal SI may correspond to at least one of the gate electrodes GE(1) and GE(2) of the first and second transistors TR(1) and TR(2). That is, a test signal may be input to at least one of the gate electrodes GE(1) and GE(2) of FIGS. 1 to 11.

For example, the test input terminal SI of the first flip-flop circuit 310a may be connected to one of the second outer connection terminals OB2 through the first front-side detection structure FDS1, the first penetration detection structure TDS1, and the first back-side detection structure BDS1. The test input terminal SI of the second flip-flop circuit 310b may be connected to another one of the second outer connection terminals OB2 through the second front-side detection structure FDS2, the second penetration detection structure TDS2, and the second back-side detection structure BDS2. The test input terminal SI of the third flip-flop circuit 310c may be connected to still other one of the second outer connection terminals OB2 through a third front-side detection structure FDS3, the penetration via TV, and a third back-side detection structure BDS3.

In the method of detecting a failure in a semiconductor device according to some embodiments of the inventive concept, the electron-beam generating and sensing device 500 may be placed below the second outer connection terminal OB2. In some embodiments, electron-beam generating and sensing device 500 may be configured to irradiate at least one of the second outer connection terminals OB2 with the first electron beam E1 and to sense the second electron beam E2 reflected or emitted from the second outer connection terminals OB2. If a failure occurs in at least one of the flip-flop circuits 310a, 310b, and 310c, the buffers 314a and 314b, and the cells 312a and 312b, the characteristics (e.g., phase shift, amplitude variation of secondary electrons, energy spectrum variation, etc.) of the second electron beam E2 may differ from those of the first electron beam E1. By using this method, it may be possible to precisely find a failure position of the semiconductor device.

According to some embodiments of the inventive concept, a semiconductor device may include a back-side detection structure, which is connected to a point for detecting a failure in a test process, and a test signal may be applied to an end portion of the back-side detection structure adjacent to a rear surface of the semiconductor device. Thus, the semiconductor device may have a structure, on which the test process can be easily performed. Furthermore, an interconnection routing step for placing the back-side detection structures may be easily executed in a process of designing the semiconductor device. In this case, since a voltage drop effect is achieved more efficiently, it may be possible to realize a semiconductor device with improved power, performance, and area characteristics.

In a method of detecting a failure in a semiconductor device according to some embodiments of the inventive concept, it may be possible to omit or minimize a process of decapsulating a front portion of the semiconductor device and to find a failure position easily and accurately.

While example embodiments of the inventive concept have been particularly shown and described, it will be understood by one of ordinary skill in the art that variations in form and detail may be made therein without departing from the spirit and scope of the attached claims. The embodiments of FIGS. 1 to 12 may be combined to realize the inventive concept.

What is claimed is:

1. A semiconductor device, comprising:
a substrate including a front surface and a rear surface, which are opposite to each other;
a first transistor adjacent the front surface of the substrate, the first transistor comprising a first gate electrode and first source/drain patterns adjacent to both sides of the first gate electrode;
a first interlayer insulating layer disposed on the first transistor;
a first front-side detection structure disposed on the first interlayer insulating layer and connected to the first gate electrode;
a first back-side detection structure adjacent the rear surface of the substrate; and
a first penetration detection structure connecting the first front-side detection structure to the first back-side detection structure,
wherein the first penetration detection structure comprises a front-side contact penetrating the first interlayer insulating layer and a first back-side contact penetrating a portion of the substrate.

2. The semiconductor device of claim 1, wherein the front-side contact is vertically overlapped with the first back-side contact.

3. The semiconductor device of claim 1, wherein the first penetration detection structure further comprises a connection conductive pattern located between the front-side contact and the first back-side contact, and
the connection conductive pattern comprises silicon.

4. The semiconductor device of claim 3, wherein the connection conductive pattern and the first source/drain patterns are doped with the same dopants.

5. The semiconductor device of claim 1, wherein the front-side contact is in contact with the first back-side contact.

6. The semiconductor device of claim 1, wherein the first transistor is included in a first flip-flop circuit.

7. The semiconductor device of claim 6, wherein a test signal is input to the first gate electrode of the first transistor at least through the front-side detection structure, the back-side detection structure and the first penetration detection structure.

8. The semiconductor device of claim 1, further comprising:
a second transistor adjacent the front surface of the substrate, the second transistor comprising a second gate electrode and second source/drain patterns adjacent to both sides of the second gate electrode;
a second front-side detection structure disposed on the first interlayer insulating layer and connected to the second gate electrode;
a second back-side detection structure adjacent the rear surface of the substrate; and
a penetration via penetrating the first interlayer insulating layer and the substrate and connecting the second front-side detection structure to the second back-side detection structure.

9. The semiconductor device of claim 8, wherein a vertical length of the first back-side detection structure is equal to a vertical length of the second back-side detection structure.

10. The semiconductor device of claim 8, wherein an upper end of the first front-side detection structure is placed at a first level,
an upper end of the second front-side detection structure is placed at a second level different from the first level,
a lower end of the first back-side detection structure is placed at a third level lower than the first level and the second level, and
a lower end of the second back-side detection structure is placed at the third level.

11. The semiconductor device of claim 10, further comprising:
a power line adjacent the rear surface of the substrate; and
a back-side interconnection structure adjacent the power line and connected to the power line,
wherein a lower end of the back-side interconnection structure is placed at a fourth level, which is equal to or lower than the third level.

12. The semiconductor device of claim 11, further comprising:
a third transistor adjacent the front surface of the substrate, the third transistor comprising a third gate electrode and third source/drain patterns adjacent to both sides of the third gate electrode; and
a second back-side contact penetrating a portion of the substrate and connecting the power line to one of the third source/drain patterns,
wherein an upper end of the second back-side contact is placed at the same level as an upper end of the first back-side contact.

13. A semiconductor device, comprising:
a substrate including a front surface and a rear surface, which are opposite to each other;
a first transistor adjacent the front surface of the substrate, the first transistor comprising a first gate electrode and first source/drain patterns adjacent to both sides of the first gate electrode;
a second transistor adjacent the front surface of the substrate, the second transistor comprising a second gate electrode and second source/drain patterns adjacent to both sides of the second gate electrode;
a first interlayer insulating layer disposed on the first transistor;
a first front-side detection structure disposed on the first interlayer insulating layer and connected to the first gate electrode;
a second front-side detection structure disposed on the first interlayer insulating layer and connected to the second gate electrode;
a first back-side detection structure adjacent the rear surface of the substrate;
a first penetration via penetrating the first interlayer insulating layer and the substrate and connecting the first front-side detection structure to the first back-side detection structure;
a second back-side detection structure adjacent the rear surface of the substrate; and
a second penetration via penetrating the first interlayer insulating layer and the substrate and connecting the second front-side detection structure to the second back-side detection structure,
wherein a first level of a lower end of the first back-side detection structure is equal to a second level of a lower end of the second back-side detection structure.

14. The semiconductor device of claim 13, wherein the first transistor is included in a first flip-flop circuit, and
a test signal is input to the first gate electrode of the first transistor at least through the first front-side detection structure, the first back-side detection structure and the first penetration via.

15. The semiconductor device of claim 13, further comprising:
a power line adjacent the rear surface of the substrate; and
a back-side interconnection structure disposed below the power line and connected to the power line,
wherein a lower end of the back-side interconnection structure is placed at a third level, which is equal to or lower than the first level of the lower end of the first back-side detection structure.

16. The semiconductor device of claim 13, wherein an upper end of the first front-side detection structure is placed at a third level higher than the first level, and
an upper end of the second front-side detection structure is placed at a fourth level that is higher than the first level and is different from the third level.

17. A semiconductor device, comprising:
a substrate including a front surface and a rear surface, which are opposite to each other;
a flip-flop circuit adjacent the front surface of the substrate;
a first transistor adjacent the front surface of the substrate, the first transistor comprising a first gate electrode and first source/drain patterns adjacent to both sides of the first gate electrode, the first transistor being included in the flip-flop circuit;
a first interlayer insulating layer disposed on the first transistor;
a first front-side detection structure disposed on the first interlayer insulating layer and connected to the first gate electrode;
a first back-side detection structure adjacent the rear surface of the substrate;
a first penetration detection structure connecting the first front-side detection structure to the first back-side detection structure;
a power line adjacent the rear surface of the substrate; and
a back-side interconnection structure disposed below the power line and connected to the power line,
wherein the first penetration detection structure comprises a front-side contact penetrating the first interlayer insulating layer, a first back-side contact penetrating a portion of the substrate, and a connection conductive pattern between the front-side contact and the first back-side contact, and
the connection conductive pattern and the first source/drain patterns are doped with the same dopants.

18. The semiconductor device of claim 17, wherein the connection conductive pattern comprises silicon.

19. The semiconductor device of claim 17, wherein a lower end of the first back-side detection structure is placed at a first level, and
a lower end of the back-side interconnection structure is placed at a second level, which is equal to or lower than the first level.

20. The semiconductor device of claim 17, wherein a test signal is input to the first gate electrode of the first transistor at least through the first front-side detection structure, the first back-side detection structure and the first penetration detection structure.
